(19) United States
(12) Patent Application Publication
(10) Pub. No.: US 2017/0330691 A1
(43) Pub. Date: Nov. 16, 2017

(54) Capacitor Module

(71) Applicant: DENSO CORPORATION, Kariya-city (JP)

(72) Inventors: Takashi MASUZAWA, Kariya-city (JP); Keisuke SUZUKI, Kariya-city (JP)

(73) Assignee: DENSO CORPORATION, Kariya-city (JP)

(21) Appl. No.: 15/591,168

(22) Filed: May 10, 2017

(30) Foreign Application Priority Data
May 12, 2016 (JP) 2016-095921
Mar. 28, 2017 (JP) 2017-063421

(51) Int. Cl. H01G 4/38; H01G 4/12; H01G 4/012; H01G 4/33; H05K 1/18

(52) U.S. Cl. CPC H01G 4/38; H01G 4/33; H05K 1/181; H01G 4/012; H01G 4/12; H05K 2201/10015

(57) ABSTRACT

A capacitor module includes a circuit board including a positive conductor part and a negative conductor part, and capacitors mounted on the circuit board. The capacitors have the same capacitance and the same inner current path structure. The capacitors are arranged in a direction perpendicular to main current directions of the inner current path structures of the capacitors. Each adjacent two of the capacitors are connected to the positive conductor part and the negative conductor part such that the main current directions thereof are opposite in direction to each other.

This application claims priority to Japanese Patent Applications No. 2016-95921 filed on May 12, 2016, and No. 2017-63421 filed on Mar. 28, 2017, the entire contents of which are hereby incorporated by reference.

### BACKGROUND OF THE INVENTION

### 1. Field of the Invention

The present invention relates to a capacitor module including a plurality of capacitors.

### 2. Description of Related Art

Generally, a power conversion apparatus is provided with a capacitor for smoothing a voltage supplied from a DC power source to a switching circuit section including switching elements thereof. When the switching elements switch on and off to intermit a current, there occurs a surge voltage due to a parasitic inductance of the power conversion apparatus. It is known to reduce such parasitic inductance by carefully choosing the layout of conductors of the power conversion apparatus.

However, a parasitic inductance caused by a current flowing through the capacitor cannot be reduced sufficiently by only contriving the layout of the conductors of the power conversion apparatus. Japanese Patent No. 4924698 discloses an electronic component mounting structure in which two capacitors are deposed such that currents flowing through the two capacitors are opposite in direction to each other.

However, in this electronic component mounting structure, if the electrostatic capacities of the two capacitors are different from each other, since magnetic fluxes due to the currents flowing through the capacitors do not sufficiently cancel out with each other, it is difficult to sufficiently reduce the parasitic inductance. Further, if inner current paths of the two capacitors are different in structure from each other, it is difficult to sufficiently reduce the parasitic inductance.

### SUMMARY

An exemplary embodiment of the invention provides a capacitor module including:

a circuit board including a positive conductor part and a negative conductor part; and

capacitors mounted on the circuit board, wherein

the capacitors have the same capacitance and the same inner current path structure,

the capacitors are arranged in a direction perpendicular to main current directions of the inner current path structures of the capacitors, and

each adjacent two of the capacitors are connected to the positive conductor part and the negative conductor part such that the main current directions thereof are opposite in direction to each other.

According to the exemplary embodiment, there is provided a capacitor module whose parasitic inductance can be made sufficiently low.

Other advantages and features of the invention will become apparent from the following description including the drawings and claims.

### BRIEF DESCRIPTION OF THE DRAWINGS

In the accompanying drawings:

FIG. 1 is a perspective view of a capacitor module according to a first embodiment of the invention;

FIG. 2 is a plan view of the capacitor module according to the first embodiment of the invention;

FIG. 3 is a side view of the capacitor module according to the first embodiment of the invention;

FIG. 4 is a front view of the capacitor module according to the first embodiment of the invention;

FIG. 5 is a perspective view showing a current path of the capacitor module according to the first embodiment of the invention;

FIG. 6 is a plan view showing the current path of the capacitor module according to the first embodiment of the invention;

FIG. 7 is a cross-sectional view of capacitor elements of the capacitor module according to the first embodiment of the invention;

FIG. 8 is a perspective view of a circuit board of the capacitor module according to the first embodiment of the invention;

FIG. 9 is a plan view of the circuit board of the capacitor module according to the first embodiment of the invention;

FIG. 10 is a circuit diagram of a power conversion apparatus including the capacitor module according to the first embodiment of the invention;

FIG. 11 is a perspective view of a capacitor module according to comparative example 1;

FIG. 12 is a plan view of the capacitor module according to comparative example 1;

FIG. 13 is a plan view of a capacitor module according to comparative example 2;

FIG. 14 is a perspective view showing a current path of a capacitor module according to a second embodiment of the invention.

FIG. 15 is a perspective view of a capacitor module according to a third embodiment of the invention;

FIG. 16 is a perspective view of a capacitor module according to a fourth embodiment of the invention;

FIG. 17 is a perspective view of a capacitor module according to a fifth embodiment of the invention; and

FIG. 18 is a perspective view of a capacitor module according to a sixth embodiment of the invention;

### PREFERRED EMBODIMENTS OF THE INVENTION

### First Embodiment

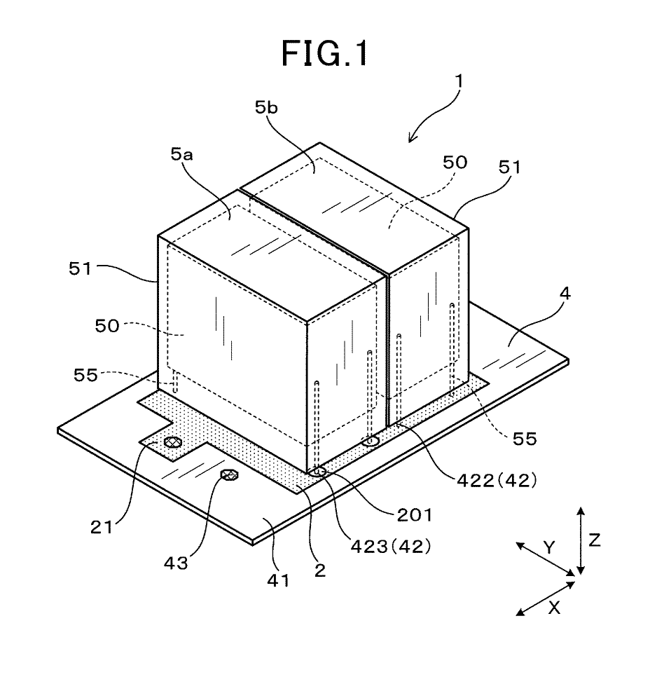

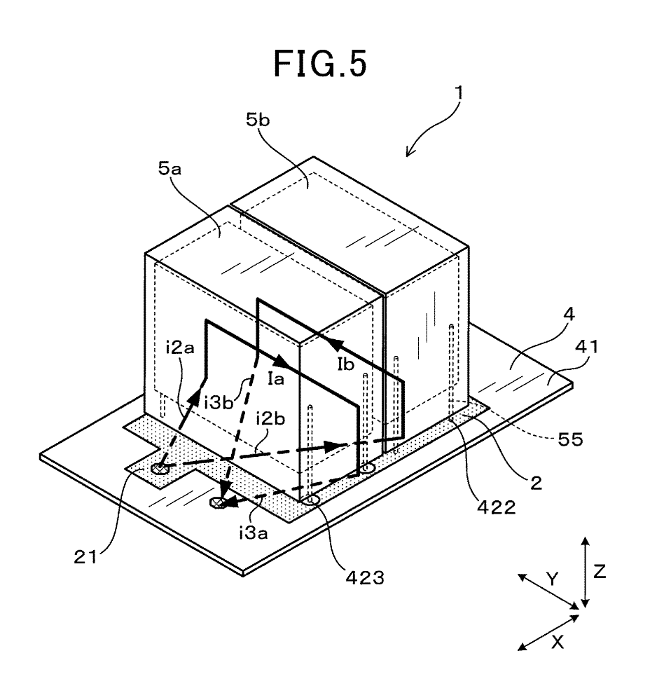

A capacitor module 1 according to a first embodiment of the invention is described with reference to FIGS. 1 to 10. As shown in FIGS. 1 to 4, the capacitor module 1 includes a circuit board 4 having a positive conductor part 2 and a negative conductor part 3, and capacitors 5a and 5b mounted on the circuit board 4.

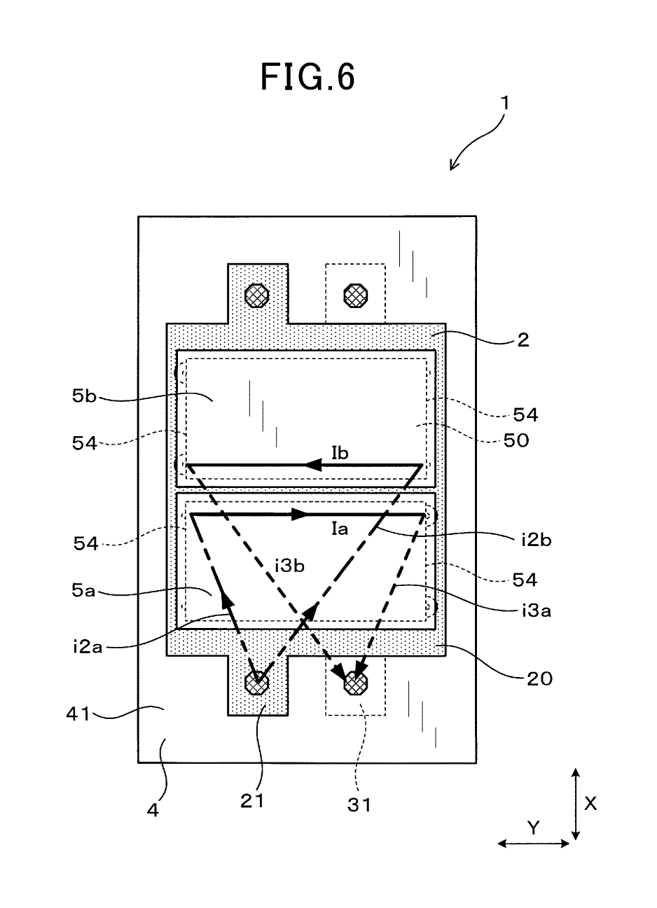

The capacitors 5a and 5b are the same as each other in capacitance and in structure of internal current path. As shown in FIGS. 5 and 6, the capacitors 5a and 5b are arranged adjacent to each other so as to align to a direction perpendicular to main current directions Ia and Ib of their internal current paths. The capacitors 5a and 5b are connected to the positive conductor part 2 and negative conductor part 3 such that the main current directions Ia and Ib are opposite to each other.

In the following, the arranging direction of the capacitors 5a and 5b may be referred to as an X direction, the normal direction of the circuit board 4 may be referred to as a Z direction, and the direction perpendicular to the X direction and the Z direction may be referred to as a Y direction. The main current directions Ia and IB are parallel to the Y direction.

The capacitor module 1 according to this embodiment includes the two capacitors 5a and 5b. The capacitors 5a and 5b, which comply with the same standard, are the same as each other in size and shape. Accordingly, the capacitors 5a and 5b are the same as each other in capacitance and structure of internal current path. Here, the capacitors 5a and 5b are regarded to be the same in capacitance if the difference between their electrostatic capacities is within an ordinary individual difference. In this embodiment, if the difference between their electrostatic capacities is smaller than 20%, they are regarded to be the same in capacitance.

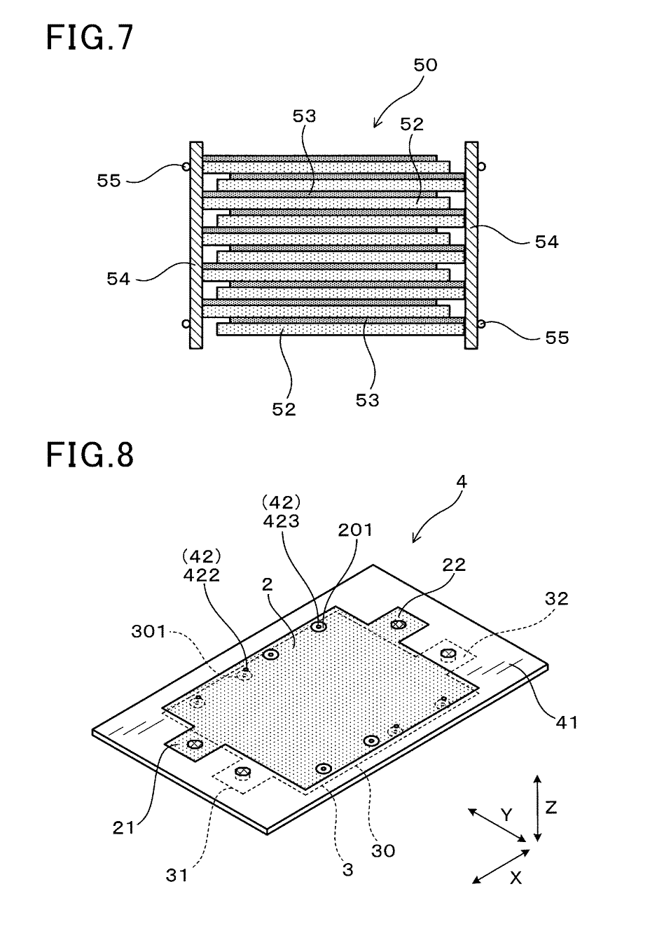

In this embodiment, the capacitors 5a and 5b are film capacitors. As shown in FIG. 7, each of the capacitors 5a and 5b includes a capacitor element 50 formed of a roll of a metalized film which is comprised of dielectric films 52 and metal films 53 each formed on a surface of the corresponding dielectric film 52. The metal films 53 make the internal electrodes. A pair of end surface electrodes 54 are provided in both end surfaces in the winding direction of the metalized film. The metal film 53 connected to one of the end surface electrodes 54 and the metal film 53 connected to the other end surface electrode 54 are disposed alternately. Each end surface electrode 54 is connected with lead parts 55. The lead parts 55, the end surface electrodes 54 and the metalized films 53 constitute the capacitors 5a and 5b. The capacitors 5a and 5b have the same structure of the internal current path. In this embodiment, the capacitor element 50 is formed of a single rolled metalized film as described above. However, the capacitor element 50 may be formed of a plurality of metalized films stacked on one another.

The capacitors 5a and 5b may be ceramic capacitors. Also in this case, the internal current path is formed by the internal electrodes, conductor parts electrically connected to the inner electrodes and a dielectric part disposed between the internal electrodes.

As shown in FIGS. 1 to 4, each of the capacitors 5a and 5b includes a case 51 housing the capacitor element 50. The case 51 is formed in a roughly parallelepiped shape which opens on the side of the circuit board 4. The case 51 is made of insulating material such as resin. The capacitor element 50 is sealed within the case 51 by a not shown sealing resin. The lead parts 55 project from the sealing resin.

For each of the capacitors 5a and 5b, the lead parts 55 are two in number which are connected to the pair of the end surface electrodes 54 of the capacitor element 50. The four lead parts 51 of the capacitors 5a and 5b are disposed so as to be parallel to one another. The two capacitors 5a and 5b having the above described structure are disposed side by side adjacent to each other in the longitudinal direction of the circuit board 4.

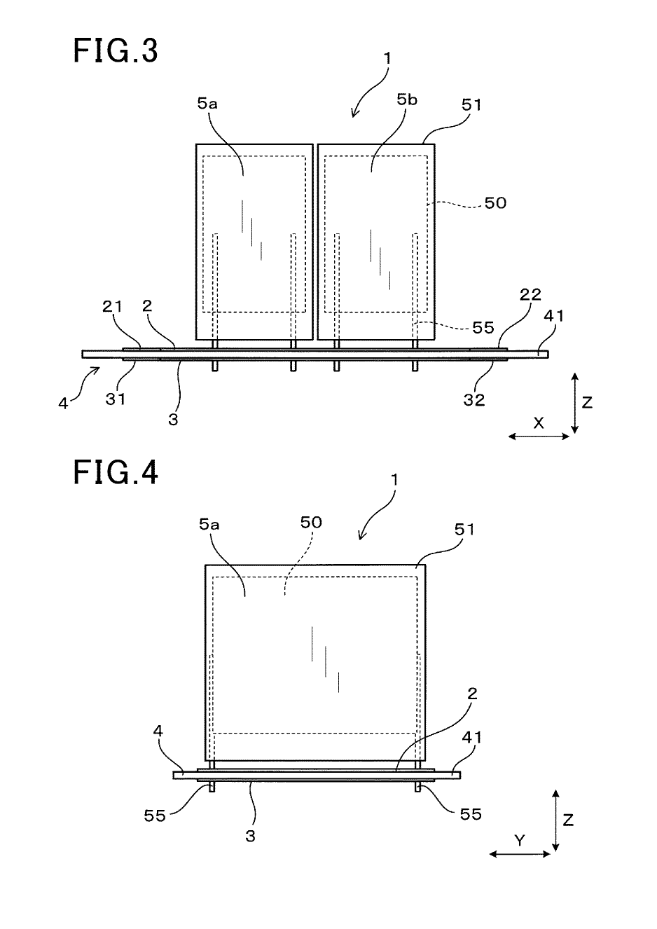

As shown in FIGS. 3, 4, 8 and 9, the circuit board 4 includes an insulating substrate 41, the positive conductor part 2 and the negative conductor part 3. The positive conductor part 2 and the negative conductor part 3 are formed on the opposite surfaces of the insulating substrate 41. Each of the positive conductor part 2 and the negative conductor part 3 is formed in a planar shape in the longitudinal direction of the principal surface of the insulating substrate 41. The positive conductor part 2 includes a main conductor part 20, and two terminal parts 21 and 31 which project from the main conductor part 20. The negative conductor part 3 includes a main conductor part 30, and two terminal parts 31 and 32 which project from the main conductor part 30.

The main conductor part 20 of the positive conductor part 2 and the main conductor part 30 of the negative conductor part 3 are disposed such that they overlap with each other when viewed in the normal direction of the circuit board 4, or in the Z direction. On the other hand, the terminal parts 21, 22, 31 and 32 are disposed such that they do not overlap with one another when viewed in the Z direction. Each of the terminal parts 21, 22, 31 and 32 is formed with a through hole 43 which penetrates through the circuit board 4.

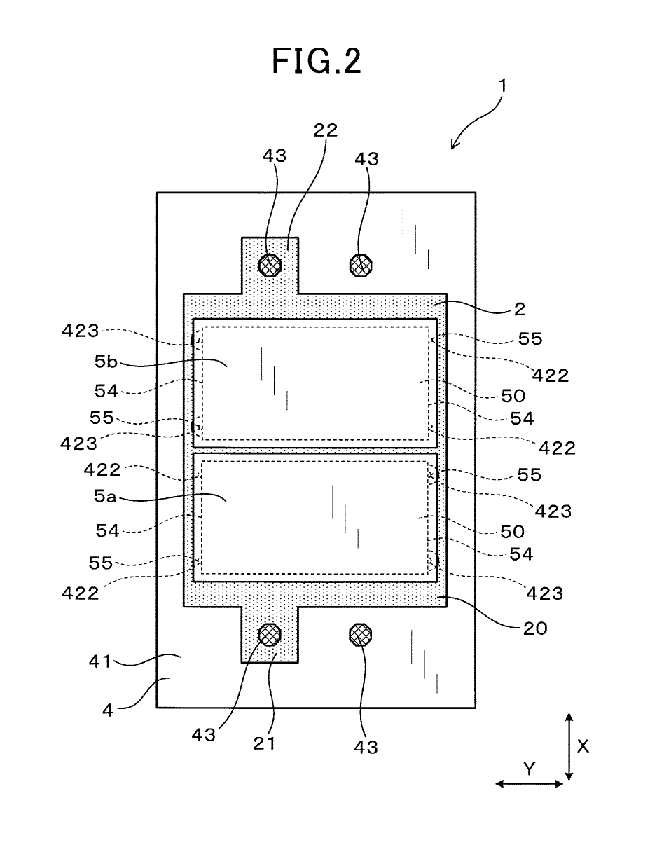

As shown in FIGS. 2 to 4, the capacitors 5a and 5b are mounted in an area where the main conductor parts 20 and 30 are formed. Accordingly, as shown in FIGS. 1, 8 and 9, through holes 42 for connection of the lead parts 55 of the capacitors 5a and 5b are formed in this area. Some of the through holes 42 are electrically connected to the positive conductor part 2. These through holes are referred to as positive through holes 422 in the following. The other through holes 42 are electrically connected to the negative conductor part 3. These through holes are referred to as negative through holes 423 in the following.

The main conductor part 30 of the negative conductor part 3 is formed with a recess 301 around each of the positive through holes 422. The main conductor part 20 of the positive conductor part 2 is formed with a recess 201 around each of the negative through holes 423. Accordingly, it is possible to prevent the positive conductor part 2 and the negative conductor part 3 from short-circuiting with each other.

As shown in FIG. 2, the two lead parts 55 of one electrode of the capacitor 5a are connected to the positive through holes 422, while the two lead parts 55 of the other electrode are connected to the negative through holes 423. The positive through holes 422 and the negative through holes 423 connected to the capacitor 5a are disposed on the opposite sides in the Y direction.

Likewise, the two lead parts 55 of one electrode of the capacitor 5b are connected to the positive through holes 422, while the two lead parts 55 of the other electrode are connected to the negative through holes 423. The positive through holes 422 and the negative through holes 423 connected to the capacitor 5b are disposed on the opposite sides in the Y direction.

The positive through holes 422 connected to the capacitor 5a and the positive through holes 422 connected to the capacitor 5b are disposed on the opposite sides in the Y direction.

The negative through holes 423 connected to the capacitor 5a and the negative through holes 423 connected to the capacitor 5b are disposed on the opposite sides in the Y direction.

The two positive through holes 422 connected to the capacitor 5a and the two negative through holes 423 connected to the capacitor 5b are arranged along a same straight line in the X direction. The two negative through holes 423 connected to the capacitor 5a and the two positive through holes 422 connected to the capacitor 5b are arranged along a same straight line in the X direction.

As shown in FIGS. 1 to 4, the capacitors 5a and 5b are mounted on the circuit board 4 by inserting and soldering the lead parts 55 in these through holes 42. Accordingly, the capacitors 5a and 5b are disposed such that the pair of the end surface electrodes 54 are arranged in the Y direction. The end surface electrode 54 as a positive electrode and the end surface electrode 54 as a negative electrode are disposed on the opposite sides in the Y direction for the two capacitors 5a and 5b. As shown in FIG. 6, since a current flows mainly in the direction from the positive end surface electrode 54 to the negative end surface electrode 54 for each of the capacitors 5a and 5b, the main current directions Ia and Ib of the two capacitors 5a and 5b are opposite to each other.

That is, the main current directions Ia and Ib of the two capacitors 5a and 5b are parallel to the Y direction and opposite to each other. The capacitors 5a and 5b are disposed at the same position with respect to the main current paths Ia and Ib. That is, the capacitors 5a and 5b are disposed at the same position in the Y direction. Since the capacitors 5a and 5b have the same size, the positions of their ends in the Y direction are the same in the Y direction.

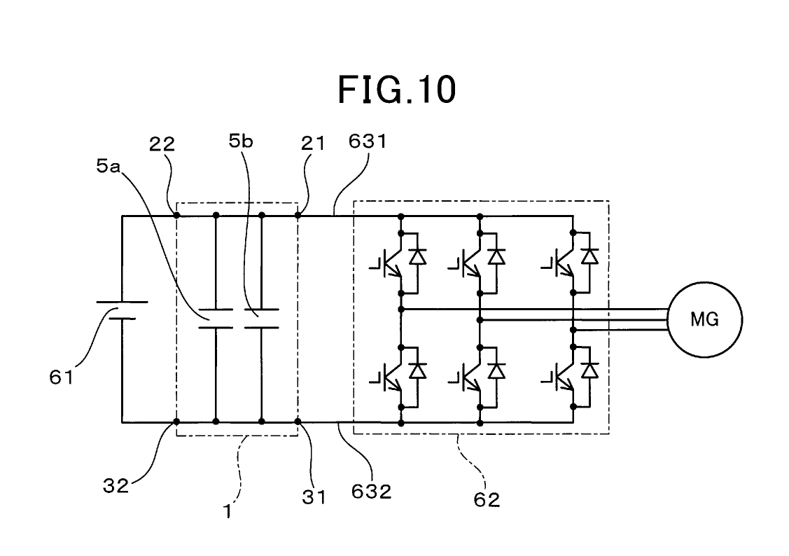

The capacitor module 1 is connected to a not shown DC power source at the terminal parts 21 and 31. More specifically, the terminal part 21 is connected to the positive electrode of the DC power source, and the terminal part 31 is connected to the negative electrode of the DC power source. The capacitor module 1 is connected to a later described switching circuit section 62 (see FIG. 10) at the terminal parts 21 and 31. Accordingly, as shown in FIGS. 5 and 6, a current supplied from the terminal part 21 flows to the capacitors 5a and 5b through the positive conductor part 2. The lead parts 55 of the capacitor 5a and the lead parts 55 of the capacitor 5b are connected to the positive conductor part 2 on the opposite sides in the Y direction. Accordingly, the current flows to the capacitors 5a and 5b from the opposite sides in the Y direction. In FIGS. 5, 6 and 9, the chain lines i2a and i2b show the directions of the currents passing through the positive conductor part 2, and the broken lines i3a and i3b show the directions of the currents passing through the negative conductor part 3.

The currents flow through the inner current paths of the capacitors 5a and 5b in the opposite directions in the Y direction. The currents flow to the negative conductor part 3 through the lead parts 55 connected to the negative conductor part 3. That is, the currents flowing out from the inner current paths of the capacitors 5a and 5b flow to the negative conductor part 3 from the opposite sides in the Y direction. These currents flow toward the terminal part 31 of the negative conductor part 3.

As explained above, the currents flow through the two current paths of the two capacitors 5a and 5b at the same time. The directions of the currents flowing through the current paths of the capacitors 5a and 5b are opposite to each other. Accordingly, the currents flow concentratedly at portions close to each other in the inner current paths by a proximity effect. Therefore, as shown in FIG. 6, the currents flowing through the capacitors 5a and 5b are higher at the portions close to each other in the X direction. As a result, most of the currents flow through the lead parts 55 which are close to each other in the X direction.

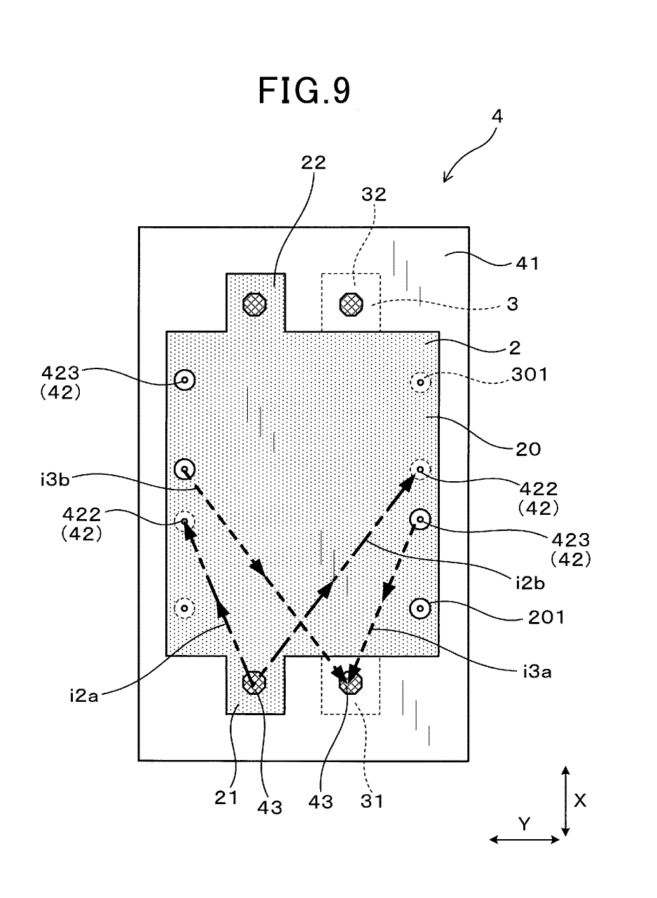

As shown in FIGS. 8 and 9, the currents i2a and i2b flowing through the positive conductor part 2 are opposite in direction to the currents i3a and i3b flowing through the negative conductor part 3. That is, the current path including the capacitor 5a is roughly opposite in direction to the current path including the capacitor 5b in both the positive conductor part 2 and the negative conductor part 3.

As shown in FIG. 10, the capacitor module 1 is connected between a DC power source 61 and the switching circuit section 62, for example. In this case, the capacitor module 1 is used as a smoothing capacitor for smoothing the voltage supplied from the DC power source 61 to the switching circuit section 62. The capacitors 5a and 5b of the capacitor module 1 are reverse parallel connected to each other. The terminal parts 22 and 32 of the capacitor module 1 are connected to the positive electrode and the negative electrode of the DC power source 61, respectively. The terminal parts 21 and 31 of the capacitor module 1 are connected to a high voltage line 631 and a low voltage line 632 of the switching circuit section 62, respectively. The same currents flow through the capacitors 5a and 5b respectively at the same time.

Next, advantageous effects of this embodiment are explained. The capacitors 5a and 5b of the capacitor module 1 are the same in capacitance and inner current path structure. Accordingly, by disposing the capacitors 5a and 5b such that the main current directions Ia and Ib are opposite in direction to each other, the parasitic inductance can be reduced effectively.

The positive conductor part 2 and the negative conductor part 3 are disposed on the opposite surfaces of the insulating substrate 41. Accordingly, it is possible to dispose the positive conductor part 2 and the negative conductor part 3 such that they overlap in the Z direction. Therefore, it is possible that a current flowing through the current path including the capacitor 5a and a current flowing through the current path including the capacitor 5b are opposite in direction to each other in not only the insides of the capacitors 5a and 5b but the whole of the capacitor module 1 including the positive conductor part 2 and the negative conductor part 3. As a result, since the magnetic fluxes cancel out with each other also in the positive conductor part 2 and the negative conductor part 3, the parasitic inductance can be reduced effectively.

The capacitors 5a and 5b are disposed such that their positions in the Y direction are the same as each other. Accordingly, the inductance in the inner paths of the capacitors 5a and 5b can be reduced effectively. As described above, according to the first embodiment described above, there is provided a capacitor module whose parasitic capacitance is sufficiently low.

### Comparative Example 1

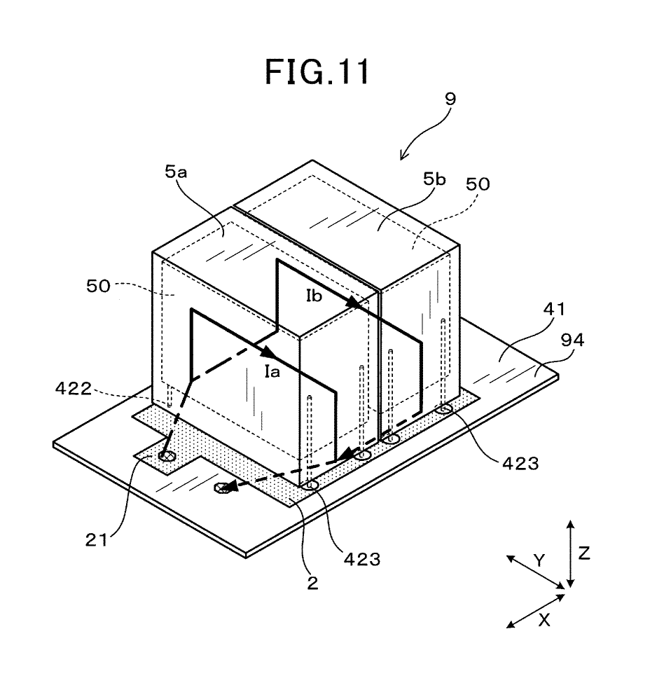

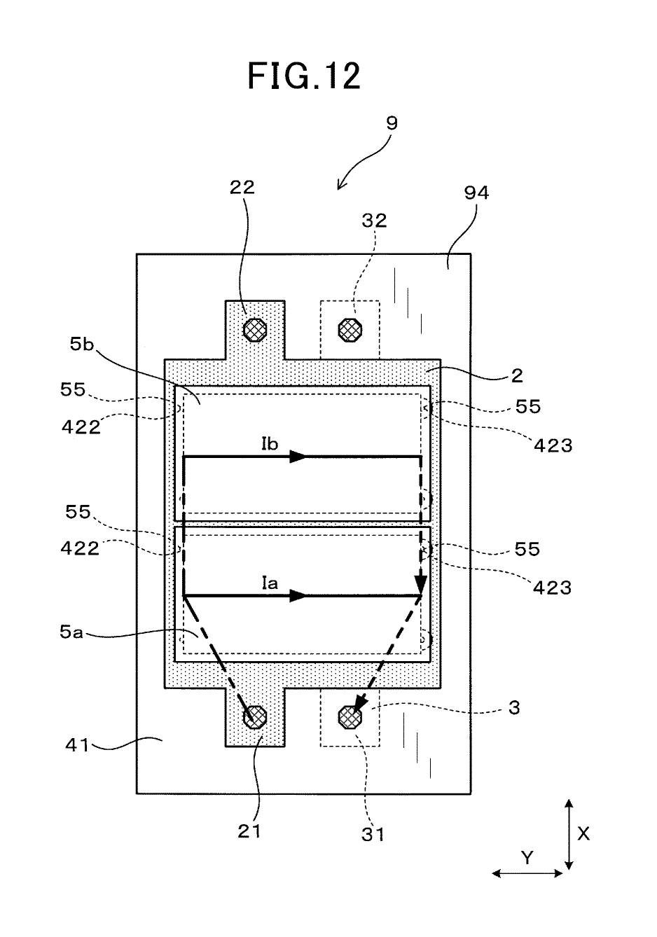

As shown in FIGS. 11 and 12, in a capacitor module 9 as comparative example 1, the capacitors 5a and 5b are wired such that their main current directions Ia and Ib are the same as each other. The capacitor module 9 has a circuit board 94 which is different in structure from the circuit board 4 of the first embodiment. The circuit board 94 is formed with the positive and negative through holes 422 and 423 which are different in arrangement from those of the circuit board 4 of the first embodiment. In comparative example 1, the positions of the lead parts 55 of the capacitors 5a and 5b connected to the positive conductor part 2 are on the same side in the Y direction. Except for the above, comparative example 1 is the same in structure as the first embodiment. Accordingly, in comparative example 1, since the main current directions Ia and Ib of the capacitors 5a and 5b are the same as each other, the magnet fluxes due to currents flowing through the capacitors 5a and 5b do not cancel out with each other, the parasitic inductance cannot be reduced.

### Comparative Example 2

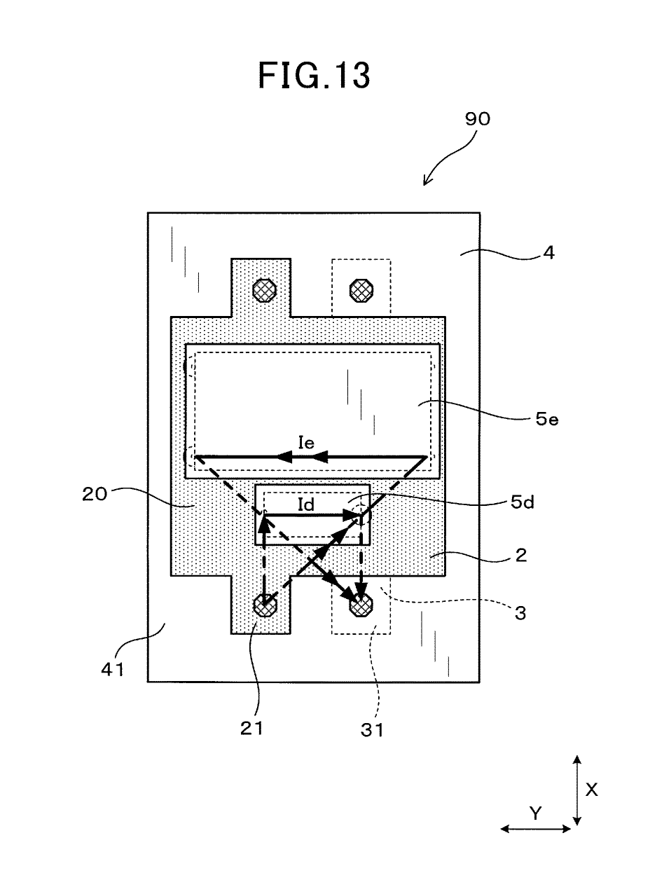

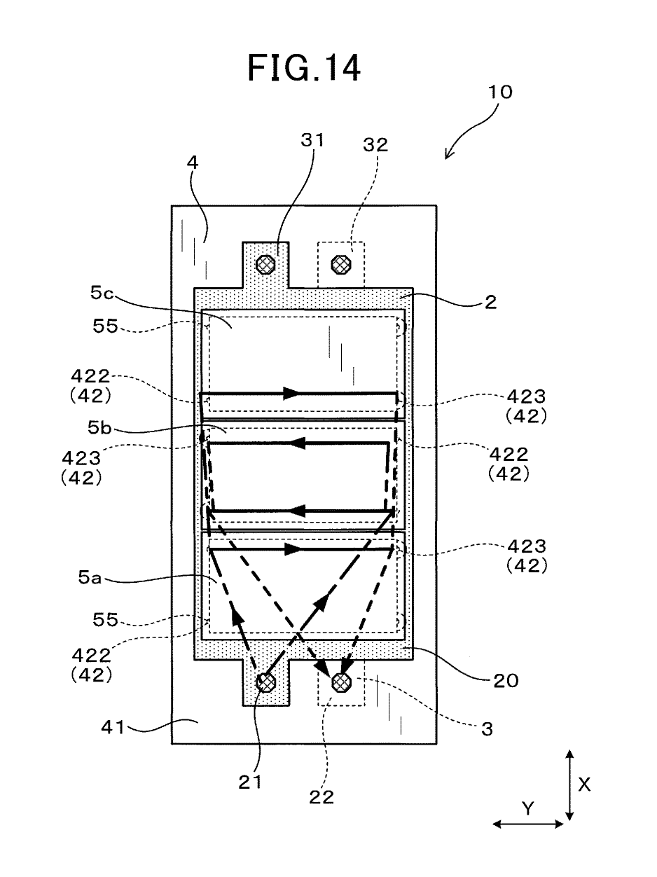

Comparative example 2 is an example of a capacitor module 90 in which the two capacitors 5a and 5b are different from each other in size and capacitance as shown in FIG. 13. In this example, even if main current directions Id and Ie of currents flowing through the capacitors 5a and 5b are opposite to each other, since the magnitudes of magnetic fluxes due to the currents are different from each other, the parasitic inductance cannot be reduced sufficiently.

### Second Embodiment

A second embodiment of the invention is an example of a capacitor module 10 in which three capacitors 5a, 5b and 5c are mounted on the circuit board 4. The capacitors 5a, 5b and 5c are the same as one another in capacitance and inner current path structure. The capacitors 5a, 5b and 5c are arranged side by side in a direction perpendicular to the main current directions Ia, Ib and Ic in the inner current paths. That is, the three capacitors 5a, 5b and 5c are arranged in the X direction.

Further, in this embodiment, each adjacent two of these capacitors are connected to the positive conductor part 2 and the negative conductor part 3 such that the main current directions Ia, Ib and Ic are opposite to one another. That is, the main current directions Ia and Ic of the capacitors 5a and 5c are opposite to the main current direction Ib of the capacitor 5b disposed between the capacitors 5a and 5c. Except for the above, the second embodiment 1 is the same in structure as the first embodiment.

For the capacitor 5b, a current flows concentratedly at the both ends in the X direction of the inner current path. That is, the current flowing through the capacitor 5b concentrates at the both ends in the X direction due to a proximity effect between the currents flowing through the adjacent capacitors 5a and 5b. As a result, for each of the capacitors 5a and 5c, the current flows concentratedly at the end closer to the capacitor 5b in the X direction.

As explained above, since the direction of the current flowing through the capacitor 5a and the direction of the current flowing through the capacitor 5c are opposite to each other, the parasitic inductance can be reduced. Other than the above, this embodiment provides the same advantages as those provided by the first embodiment.

### Third Embodiment

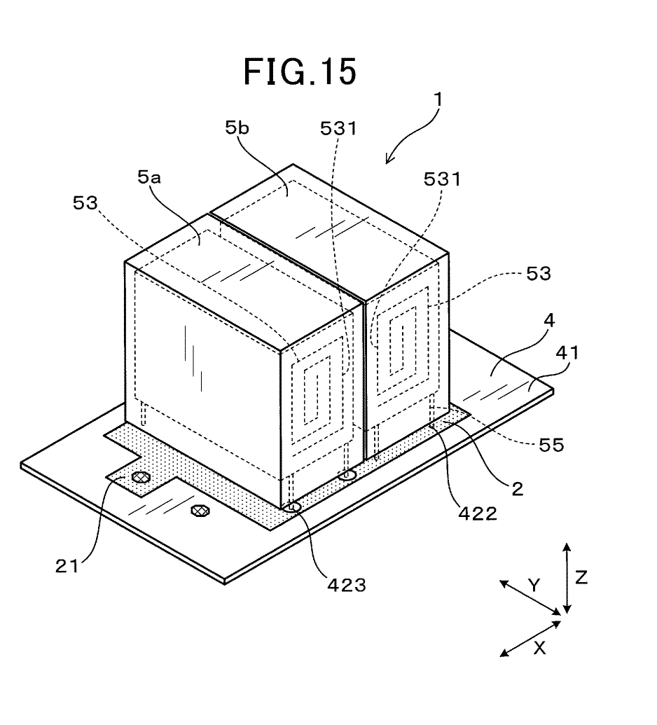

In a third embodiment of the invention, as shown in FIG. 15, the capacitors 5a and 5b, which are disposed adjacent to each other, include opposing planar parts 531 within the inner electrodes, which are opposite to each other. That is, each of the capacitors 5a and 5b includes a roll of metalized film. As in the first embodiment, the metalized film is comprised of a dielectric film 52 and a metal film 53 formed on the surface of the dielectric film 52. The metal film 53 forms the inner electrode 53.

The opposing planar parts 531 which are opposite to each other are formed in the metal films 53. That is, the portion of the metal film 53 as the inner electrode of the capacitor 5a and the portion of the metal film 53 as the inner electrode of the capacitor 5b, which are opposite to each other, are formed in a planar shape. These portions formed in a planar shape are the opposing planar parts 531. The opposing planar parts 531 are parallel to each other. Except for the above, the third embodiment is the same in structure as the first embodiment.

In this embodiment, the capacitors 5a and 5b disposed adjacent to each other include the opposing planar parts 531 which are opposed to each other. This makes it possible that most of the currents flowing through the capacitors 5a and 5b respectively are close and opposite to each other. As a result, the parasitic inductance can be reduced more effectively. Other than the above, this embodiment provides the same advantages as those provided by the first embodiment.

### Fourth Embodiment

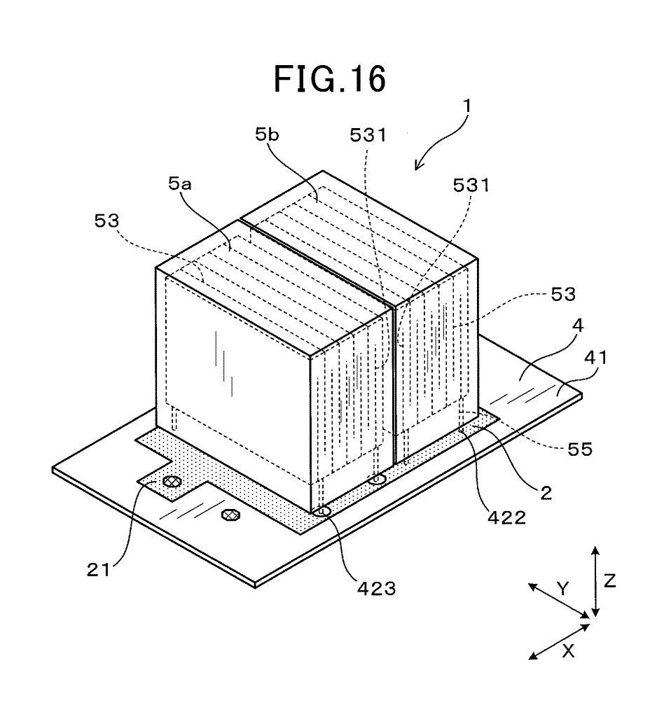

In a fourth embodiment of the invention, as shown in FIG. 16, the adjacent capacitors 5a and 5b include opposing planar parts 531 at their inner electrodes. In this embodiment, each of the capacitors 5a and 5b includes a stack of metalized films. Accordingly, metal films 53 are in a stacked state. The stacking direction of the metal films 53 is parallel to the X direction, that is, parallel to the arranging direction of the capacitors 5a and 5b.

Accordingly, the portion of the metal film 53 as the inner electrode of the capacitor 5a and the portion of the metal film 53 as the inner electrode of the capacitor 5b, which are opposite to each other, are formed in a planar shape. These planar portions make the opposing planar parts 531. The opposing planar parts 531 are parallel to each other. Except for the above, the fourth embodiment is the same in structure as the first embodiment.

According to this embodiment, the parasitic inductance can be reduced effectively like the third embodiment.

Other than the above, this embodiment provides the same advantages as those provided by the first embodiment.

### Fifth Embodiment

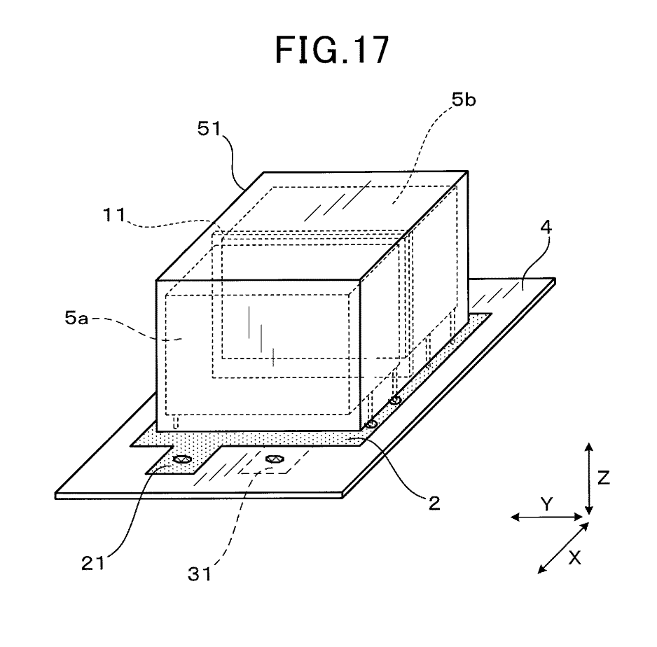

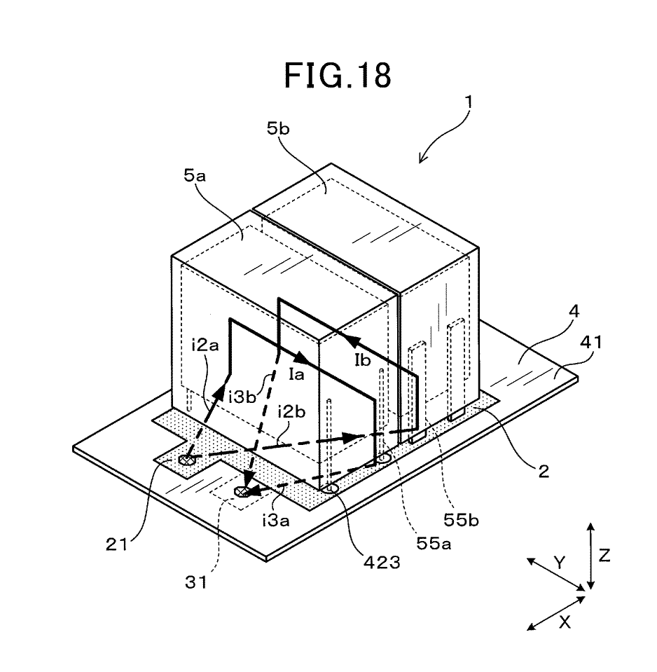

In a fifth embodiment of the invention, as shown in FIG. 17, the adjacent capacitors 5a and 5b are in contact with each other at their principal surfaces through an insulating layer 11. The capacitors 5a and 5b are housed in the single case 51 together with the insulating layer 11. The insulating layer 11 may be a sheet of insulating paper. Except for the above, the fifth embodiment is the same in structure as the first embodiment.

According to this embodiment, the capacitors 5a and 5b can be disposed more closely to each other while ensuring insulation therebetween. Accordingly, since the magnetic fluxes due to currents flowing through the capacitors 5a and 5b can be cancelled out more effectively, the parasitic inductance can be reduced more effectively. Other than the above, this embodiment provides the same advantages as those provided by the first embodiment.

### Sixth Embodiment

In a sixth embodiment of the invention, as shown in FIG. 18, the impedance of a connection wiring for connection between the inner electrode and the circuit board for one of the capacitors 5a and 5b, which is more distant from the terminal parts 21 and 31 than the other capacitor, is set smaller than that for the other capacitor. The positive conductor part 2 and the negative conductor part 3 are disposed such that the terminal parts 21 and 31 electrically connected to the switching circuit section 62 (see FIG. 10) are located on the same side in the longitudinal direction of the circuit board 4. In this embodiment, the terminal parts 21 and 31 are located on the same side in the X direction.

The capacitors 5a and 5b are arranged in the X direction. The capacitor 5b is more distant from the terminal parts 21 and 31 than the capacitor 5b is. The impedance of the connection wiring for connection between the inner electrode of the capacitor 5b and the circuit board 4 is smaller than the impedance of the connection wiring for connection between the inner electrode of the capacitor 5a and the circuit board 4.

The connection wirings include the end surface electrodes and the lead parts 55a and 55b of the capacitors 5a and 5b. In this embodiment, the impedance of the lead parts 55b of the capacitor 5b is made smaller than the impedance of the lead parts 55a of the capacitor 5a. Specifically, the cross-sectional area in the direction perpendicular to the current direction of the lead parts 55b is made larger than that of the lead parts 55a. More specifically, the lead parts 55a are formed in a pin shape, while the lead parts 55b are formed in a plate shape.

The lead parts 55a and 55b may be made different in inductance by making them different from each other in material. Further, the impedances of the connection wirings may be made different by making the impedances of the end surface electrodes of the capacitors 5a and 5b different from each other. Except for the above, the sixth embodiment is the same in structure as the first embodiment.

In this embodiment, the impedance of the connection wiring (the lead part 55b, for example) of the capacitor 5b, which is more distant from the terminal parts 21 and 31 than the capacitor 5a, is made smaller than that of the capacitor 5a. This makes it possible to make the impedance of the whole current path including the inner current path of the capacitor 5a and the impedance of the whole current path including the inner current path of the capacitor 5b closer to each other. The current path from the terminal parts 21 and 31 to the capacitor 5a is greater in length and accordingly greater in impedance than the current path from the terminal parts 21 and 31 to the capacitor 5b. Accordingly, in this embodiment, the impedance of the connection wiring (the lead part 55b, for example) of the capacitor 5b is made smaller than the impedance of the connection wiring (the lead part 55a, for example) of the capacitor 5a. As a result, since the difference between the currents flowing through the capacitors 5a and 5b can be reduced, the parasitic inductance can be reduced greatly. Other than the above, this embodiment provides the same advantages as those provided by the first embodiment.

It is a matter of course that various modifications can be made to the above described embodiments. For example, although the capacitors are disposed on the circuit board 4 at the side where the positive conductor part 2 is disposed in the above embodiments, they may be disposed at the side where the negative conductor part 3 is disposed. In the above embodiments, although each of the capacitors includes two pairs of lead parts, each capacitor may include a single pair of lead parts.

The above explained preferred embodiments are exemplary of the invention of the present application which is described solely by the claims appended below. It should be understood that modifications of the preferred embodiments may be made as would occur to one of skill in the art.

What is claimed is:

1. A capacitor module comprising:
a circuit board including a positive conductor part and a negative conductor part; and
capacitors mounted on the circuit board, wherein
the capacitors have the same capacitance and the same inner current path structure,
the capacitors are arranged in a direction perpendicular to main current directions of the inner current path structures of the capacitors, and
each adjacent two of the capacitors are connected to the positive conductor part and the negative conductor part such that the main current directions thereof are opposite in direction to each other.

2. The capacitor module according to claim 1, wherein the circuit board includes an insulating substrate and the positive and negative conductor parts, the positive and negative conductor parts being formed on opposite surfaces of the insulating substrate.

3. The capacitor module according to claim 1, wherein the capacitors are disposed such that positions of the capacitors in the main current directions are the same as one another.

4. The capacitor module according to claim 1, wherein the capacitors are film capacitors.

5. The capacitor module according to claim 1, wherein the capacitors are ceramic capacitors.

6. The capacitor module according to claim 1, wherein each adjacent two of the capacitors include opposing planar parts in internal electrodes thereof, the opposing planar parts being opposed to each other.

7. The capacitor module according to claim 1, wherein each adjacent two of the capacitors are in contact with each other through an insulating layer.

8. The capacitor module according to claim 1, wherein
the positive and negative conductor parts are disposed such that terminal parts thereof electrically connected to an external switching circuit section are located on the same side in a longitudinal direction of the circuit board, and
each of the capacitors includes a connection wiring for connection between the inner electrode and the circuit board, impedances of the connection wirings of the capacitors being made smaller as distances of the capacitors to the terminal parts become greater.
